(19) United States
(12) Patent Application Publication
(10) Pub. No.: US 2007/0166918 A1
(43) Pub. Date: Jul. 19, 2007

(54) NON-VOLATILE MEMORY DEVICE, AND MANUFACTURING METHOD AND PROGRAMMING METHOD THEREOF

(75) Inventors: Sang Hyun Oh, Anyang-si (KR); Jung Ryul Ahn, Namyangju-si (KR); II Young Kwon, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,585

(22) Filed: Dec. 29, 2006

(30) Foreign Application Priority Data
Jan. 4, 2006 (KR) 10-2006-000909
Dec. 20, 2006 (KR) 10-2006-130846

(51) Int. Cl. G11C 16/04; H01L 29/788; H01L 21/336

(52) U.S. Cl. 438/257; 365/185.01; 257/315

(57) ABSTRACT

A non-volatile memory device includes a plurality of select lines and a plurality of word lines formed over a semiconductor substrate, a contact plug formed between the select lines, and a conductive interference shielding line formed between the select line and a word line adjacent to the select line and isolated from the semiconductor substrate. A method of manufacturing a non-volatile memory device includes the steps of providing a semiconductor substrate in which a plurality of select lines and a plurality of word lines are formed, forming a first insulating layer over the semiconductor substrate including the select lines and the word lines, removing the first insulating layer between the select lines, forming a conductive interference shielding line over the first insulating layer between the select line and a word line adjacent to the select line, forming a second insulating layer over the semiconductor substrate including the conductive interference shielding line, etching the second insulating layer to expose the semiconductor substrate and the conductive interference shielding line between the select lines, thus forming a contact hole, and forming a contact plug within the contact hole.

### CROSS-REFERENCES TO RELATED APPLICATIONS

The present application claims priority to Korean patent application number 10-2006-000909 filed over Jan. 4, 2006 and Korean patent application number 10-2006-130846 filed over Dec. 20, 2006, which are incorporated by reference in its entirety.

### BACKGROUND OF THE INVENTION

The present invention relates, in general, to a non-volatile memory device and, more particularly, to a non-volatile memory device, and a manufacturing method and programming method thereof, in which variation in the threshold bias of unprogrammed memory cells at the time of a program operation can be minimized.

A non-volatile memory device has a property that stored data are not erased although the supply of power is stopped. A representative non-volatile memory device includes a flash memory device. The flash memory device can be classified into a NOR flash memory device and a NAND flash memory device depending over the structure of a memory cell array.

Of them, the NAND flash memory device includes a memory cell array as a basic block unit. Each block has a number of strings. The string includes a select transistor and a memory cell. In more detail, the string includes a drain select transistor connected to bit lines, a source select transistor connected to a common source, and may pieces of memory connected in series between the drain select transistor and the source select transistor.

The drain select transistor has a gate connected to gates of drain select transistors included in other string. The connected gates become drain select lines. The source select transistor has a gate connected to gates of source select transistors included in other string. The connected gates become source select lines. The memory cell has a gate connected to gates of memory cells included in other string. The connected gates become word lines.

The NAND flash memory device including the strings store data through a program operation for injecting electrons into the floating gate. Before the program operation is executed, corresponding memory cells are all erased. In other words, the program operation is not performed until electrons injected into the floating gate are all discharged by an erase operation so that the memory cells become an erase state. At the time of the program operation over the whole memory device, a high program bias of 15 to 20 V is applied to selected word lines, and a pass bias of 9 to 10 V is applied to the remaining word lines in order to turn over the memory cells.

Meanwhile, the memory cells connected to the word lines are not all programmed, but some of the memory cells must maintain an erase state according to data to be stored. Accordingly, 0 V is applied to bit lines connected to a string including a memory cell over which the program operation will be performed, and a program disturb voltage, for example, Vcc is applied to bit lines connected to a string including a memory cell that must maintain an erase state in order to disturb the program operation.

If the program disturb voltage is applied, the voltage difference decreases because the program voltage is transferred to a channel region though a high program voltage is applied to the word lines. Thus, the program operation is not performed. However, in a memory cell adjacent to the select transistor, the threshold voltage is varied due to hot carrier injection. This phenomenon is described below.

FIG. 1 is a cross-sectional view illustrating variation of the threshold voltage in a memory cell adjacent to a select transistor at the time of a program operation in the related art.

Referring to FIG. 1, a drain 110 and a source 115 of a string including a memory cell that must maintain an erase state at the time of a program operation are applied with a power supply voltage Vcc through a bit line BL0 and a common source line CSL, respectively. A drain select line DSL is applied with the power supply voltage Vcc, and a source select line SSL is applied with a ground voltage 0V.

In this state, a channel boosting phenomenon occurs (\textcircled{1}) over a surface of a semiconductor substrate 100 due to a high bias applied to word line WL0 to WL31 at the time of a program operation. GIDL (gate induced drain leakage) current is generated (\textcircled{2}) at an edge portion A where the junction of a memory cell M0 connected to a selected word line WL0 and an adjacent source select transistor SST is shared due to a high junction potential. Hot carriers of electron-hole pairs are also generated by a strong corner field caused by the channel boosting potential.

Hot electrons of the hot carriers are moved into the cell string by means of a lateral electric field caused by the channel boosting potential (\textcircled{3}). In more detail, hot carriers are generated (\textcircled{4}) in a channel region 105 under the memory cell M0 connected to the word line WL0 to which a program voltage 18 V is applied. Hot electrons of the hot carriers generated in the channel region 105 under the word line WL0 are injected (\textcircled{5}) into a floating gate 130 of the memory cell M0 by means of a vertical electric field generated by the program voltage 18V.

In this mechanism, the electrons formed at the edge portion A where the junction of the memory cell M0 connected to the word line WL0 adjacent to the source select transistor SST, and the source select transistor SST is shared are accelerated while moving toward the word line WL0 adjacent to the source select transistor SST by means of the channel boosting potential, and thus have a hot electron property of the degree that the word line WL0 can be programmed.

Due to this, at the time of the program operation, the threshold voltage Vth of the flash memory cell M0 connected to the word line WL0 adjacent to the source select transistor SST is changed. A similar phenomenon also occurs in a memory cell M31 connected to a word line WL31 adjacent to the drain select transistor DST. It may lead to a varied threshold voltage Vth.

Furthermore, a parasitic capacitor C100 exists between the word line and the select line (in particular, the drain select line). A problem arises because the threshold voltage Vth varies even in the select transistor and the memory cell due to capacitance coupling of the parasitic capacitor C100.

If the threshold voltage of a memory cell that must maintain an erase state at the time of the program operation is changed due to hot carrier injection or capacitance coupling between the word line and the select line as described above, data stored in the memory cell is changed.

### SUMMARY OF THE INVENTION

Accordingly, the present invention addresses the above problems, and provides a non-volatile memory device, and a manufacturing method and programming method thereof, in which variation in the threshold voltage of unprogrammed memory cells at the time of a program operation can be minimized.

According to an aspect of the present invention, a non-volatile memory device includes a plurality of select lines and a plurality of word lines formed over a semiconductor substrate, a contact plug formed between the select lines, and an interference shielding line formed between the select line and a word line adjacent to the select line and isolated from the semiconductor substrate, wherein the select line comprises a source select line or a drain select line or, both, and the interference shielding line is formed between the drain select line and a word line adjacent to the drain select line and between the source select line and a word line adjacent to the source select line, and is isolated from the semiconductor substrate, and including conductive material.

According to another aspect of the present invention, a method of manufacturing a non-volatile memory device includes the steps of providing a semiconductor substrate in which a plurality of select lines and a plurality of word lines are formed, forming a first insulating layer over the semiconductor substrate including the select lines and the word lines, removing the first insulating layer between the select lines, forming a conductive interference shielding line over the first insulating layer between the select line and a word line adjacent to the select line, forming a second insulating layer over the semiconductor substrate including the interference shielding line, etching the second insulating layer to expose the semiconductor substrate and the conductive interference shielding line between the select lines, thus forming a contact hole, and forming a contact plug within the contact hole.

According to still another aspect of the present invention, a method of programming a non-volatile memory device includes the steps of providing a non-volatile memory device in which a plurality of word lines and a plurality of select lines are formed over a semiconductor substrate, and an interference shielding line isolated from the semiconductor substrate is formed between the word line and the select line, and performing a program operation while applying a negative potential bias to the interference shielding line.

According to still another aspect of the present invention, a method of programming a non-volatile memory device includes the steps of providing a non-volatile memory device in which a plurality of word lines and a plurality of select lines are formed over a semiconductor substrate, and a first interference shielding line isolated from the semiconductor substrate is provided between the word line and the select line, and performing a program operation while applying a positive potential bias to the first interference shielding line.

According to still another aspect of the present invention, a non-volatile memory device includes a cell gate including a floating gate and a control gate, an insulating layer formed over the cell gate, and a interference shielding line formed over the insulating layer, the interference shielding line being provided over the cell gate and including conductive material.

According to still another aspect of the present invention, a method of manufacturing a non-volatile memory device includes forming a cell gate including a floating gate and a control gate over a semiconductor substrate, forming an insulating layer over the cell gate and the semiconductor substrate, and forming an interference shielding line of conductive material over the insulating layer.

According to still another aspect of the present invention, a method of manufacturing a non-volatile memory device includes forming first and second cell gates over a semiconductor substrate, forming an insulating layer over the first and second cell gates, and forming an interference shielding line over the insulating layer and between the first and second cell gates.

### BRIEF DESCRIPTION OF THE DRAWINGS

FIG. 1 is a cross-sectional view illustrating variation of the threshold voltage in a memory cell adjacent to a select transistor at the time of a program operation in the related art.

FIGS. 2A to 2E are cross-sectional views illustrating a method of manufacturing a non-volatile memory device according to an embodiment of the present invention.

FIG. 3 is a circuit diagram illustrating a method of programming a non-volatile memory device according to a first embodiment of the present invention.

FIG. 4 is a circuit diagram illustrating a method of programming a non-volatile memory device according to a second embodiment of the present invention.

FIG. 5 is a timing diagram illustrating bias applied in the program method of FIG. 4.

FIGS. 6A to 6C are cross-sectional views sequentially illustrating a method of manufacturing a flash memory device according to another embodiment of the present invention.

### DETAILED DESCRIPTION OF EMBODIMENTS

Now, specific embodiments according to the present patent will be described with reference to the accompanying drawings.

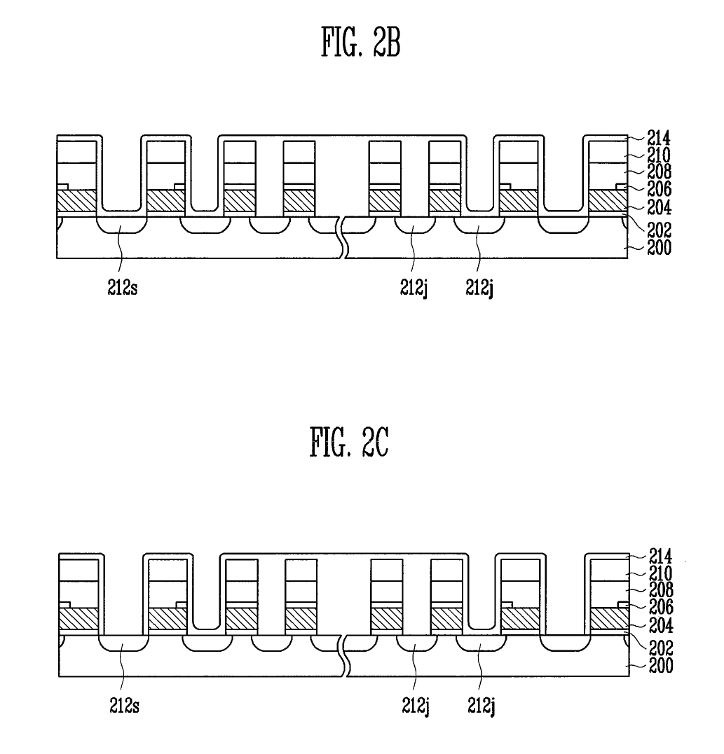

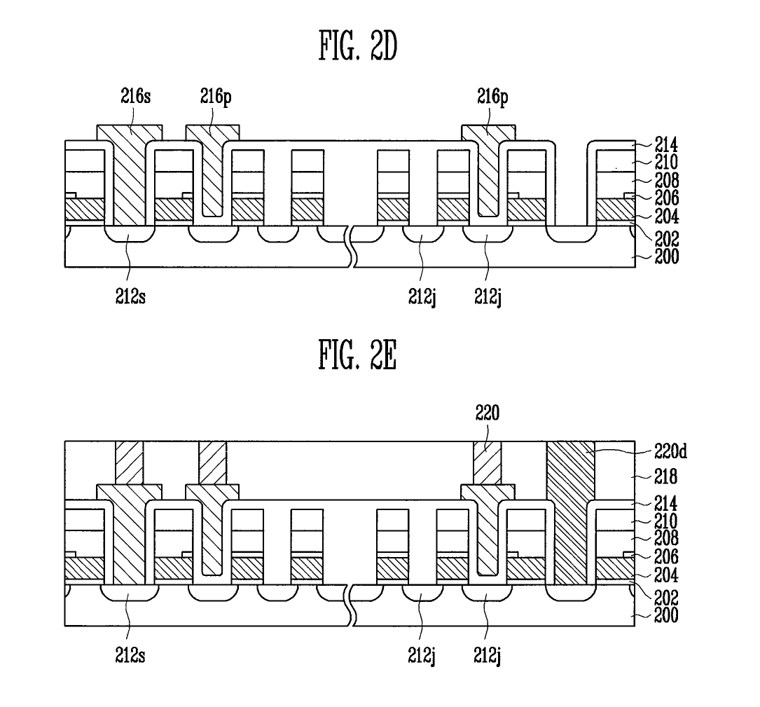

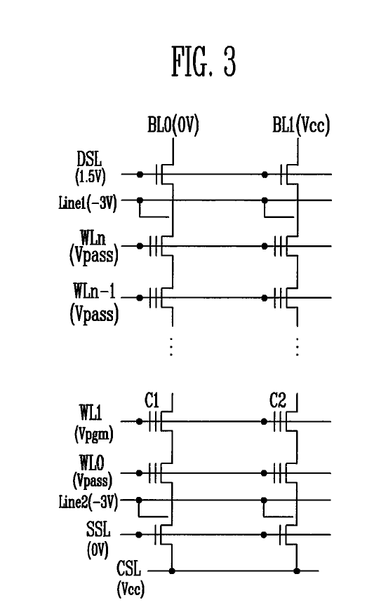

FIGS. 2A to 2E are cross-sectional views illustrating a method of manufacturing a non-volatile memory device according to an embodiment of the present invention.

Referring to FIG. 2A, a plurality of select lines DSL and SSL and word lines WL0 to WLn are formed over a semiconductor substrate 100. A junction region 212j, a drain 212d and a source 212s are formed between the select lines and the word lines. In more detail, the plurality of word lines WL0 to WLn between the drain select line DSL and the source select line SSL. The drain 212d to be connected to a bit line is formed in the semiconductor substrate 200 between the drain select lines DSL, and the source 212s is formed in the semiconductor substrate 200 between the source select lines SSL.

Meanwhile, each of the select lines DSL and SSL and the word lines WL0 to WLn include a tunnel insulating layer 202, an electron storage layer 204, a dielectric layer 206, a control gate 208 and a hard mask 210. In the select lines DSL and SSL, a portion of the dielectric layer 206 is removed, so that the electron storage layer 204 is connected to the control gate 208. The drain select line DSL, the source select line SSL, and the word lines WL0 to WLn formed between the select lines form one string.

Meanwhile, a gap between the select lines is wider than that between the word lines. Further, a gap between the select line and the word line is wider than that between the word lines, but narrower than that between the select lines.

Referring to FIG. 2B, a first insulating layer 214 is formed over the semiconductor substrate 200 including the select lines DSL and SSL and the word lines WL0 to WLn. The first insulating layer 214 can be formed of an oxide layer, a nitride layer, or a lamination structure of an oxide layer and a nitride layer.

Meanwhile, the first insulating layer 214 can be formed to a thickness to the extent that between-the word lines is completely filled, and between-the select lines and between-the select line and the word line are partially filled. In more detail, since a gap between the word lines is the narrowest, the first insulating layer 214 is thickly formed, so that between the word lines is filled with the first insulating layer 214. Further, since a gap between the select lines is the widest, the first insulating layer 214 is thinly formed. Meanwhile, a gap between word lines adjacent to the select line is narrower than that between the select lines, but wider than that between the word lines.

Accordingly, the first insulating layer 214 between the word lines adjacent to the select line is formed thicker than the first insulating layer 214 between the select lines. However, a gap between the word lines adjacent to the select line is not fully filled with the first insulating layer 214 as between the word lines.

Referring to FIG. 2C, an etch process is performed so that a portion of the drain 212d and the source 212s is exposed. In more detail, since the first insulating layer 214 has a different thickness depending over a gap between the select line and the word line, the etch process is performed by setting a target etch thickness based over the thickness of the first insulating layer 214, which is the narrowest between the select lines.

Consequently, between the select lines, the first insulating layer 214 over the source 212s or the drain 212d remains in spacer form only over the sidewalls where the select lines are opposite to each other while it is removed. Accordingly, the source 212s and the drain 212d are exposed. The first insulating layer 214 is the thickest between the word lines. Thus, although the etch process is performed, the first insulating layer 214 remains without being changed between the word lines.

Meanwhile, the first insulating layer 214 between the word lines adjacent to the select line is formed thicker than the first insulating layer 214 between the select lines. Accordingly, the semiconductor substrate 200 is etched to the extent that it is not exposed. In other words, only the thickness of the first insulating layer 214 become shallow, so that it remains only surfaces of the select line, the word lines and the semiconductor substrate.

Referring to FIG. 2D, between-the select lines and between the select line and the word lines are filled with conductive material to form a contact plug 216s and a conductive interference shielding line 216p. The conductive material comprises at least one of polysilicon, titanium, cobalt or tungsten, or combination thereof. In more detail, a conductive layer is formed over the semiconductor substrate 200 so that between-the source select lines SSL and between-the select lines DSL and SSL and the word lines WL0 and WLn are filled. In this case, a patterning process is performed such that the conductive layer remains only between the source select lines SSL and between the select line DSL and SSL and the word lines WL0 and WLn.

The patterning process can be performed by a Chemical Mechanical Polishing (CMP) process using the first insulating layer 214 as a polishing-stop layer. Alternatively, the patterning process can be performed in such a manner that a photoresist is coated over the conductive layer, a photoresist pattern is formed by photolithography and development processes, and the conductive layer is etched by an etch process employing the photoresist pattern. In the case where the patterning process is performed by the latter method, the conductive layer can be patterned so that a top width is wider than a bottom width.

Consequently, the source contact plug 216s is formed between the source select lines SSL. The source contact plug 216s can be formed in line form between the source select lines SSL. In a similar way, the conductive interference shielding line 216p is formed between the source select line SSL and the word line WL0 and between the drain select line DSL and the word line WLn. The conductive interference shielding line 216p can be formed in line form between the source select line SSL and the word line WL0 and between the drain select line DSL and the word line WLn. The source contact plug 216s and the conductive interference shielding line 216p can be formed of metal, such as tungsten, or polysilicon.

Referring to FIG. 2E, a second insulating layer 218 is formed over the semiconductor substrate 200 including the conductive interference shielding line 216p. A contact hole through which a portion of the source contact plug 216s, the conductive interference shielding line 216p and the drain 212d is exposed is formed in the second insulating layer 218. A drain contact lug 220d is formed within the contact hole over the drain 212d. At this time, an upper contact plug 220 is formed in the contact hole over the source contact plug 216s and the conductive interference shielding line 216p.

Though not shown in the drawings, a conductive material layer is formed over the second insulating layer 218 including the plugs 220 and 220d and is then patterned to form a bit line (not shown) and a metal line (not shown).

It has been described that the conductive interference shielding line 216p is formed between the source select line SSL and the word line WL0 and between the drain select line DSL and the word line WLn. However, the conductive interference shielding line 216p may be formed between the source select line SSL and the word line WL0 or between the drain select line DSL and the word line WLn.

In other words, if it is sough to hinder the movement of hot carriers, the conductive interference shielding line 216p can be formed only between the source select line SSL and the word line WL0. If it is sough to remove capacitance coupling between the drain select line DSL and the word line WLn, the conductive interference shielding line 216p can be formed only between the drain select line DSL and the word line WLn.

A method of preventing the threshold voltage of the memory cell adjacent to the select transistor from varying by applying bias to the conductive interference shielding line 216p at the time of the program operation in order to hinder the movement of hot carriers or remove capacitance coupling is described below.

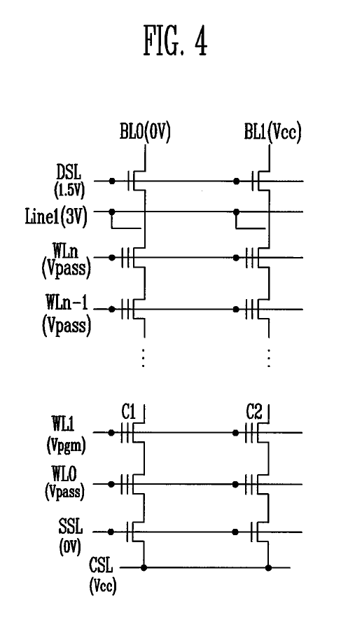

FIG. 3 is a circuit diagram illustrating a method of programming a non-volatile memory device according to a first embodiment of the present invention.

Referring to FIG. 3, a high program voltage Vpgm of 15 to 20 V is applied to a word line, for example, WL1, which is selected at the time of a program operation. The program voltage Vpgm is applied while increasing the level in an ISPP manner. This method has been well known in the art and will not be described in detail.

A pass voltage Vpass is applied to unselected word lines, for example, WL0, and WL2 to WLn so that the memory cell is turned unconditionally. The drain select line DSL is applied with a bias of about 1.5 V, and the source select line SSL is applied with a ground voltage 0V. The common source line CSL is applied with a power supply voltage Vcc. A bit line BL0 connected to a string including a to-be-programmed memory cell C1 is applied with the ground voltage 0V, and a bit line BL1 connected to a string including a memory cell C0 not to be programmed is applied with hindering voltage, for example, Vcc.

Conductive interference shielding lines Line1 and Line2 formed between the select line and the word line are applied with voltage of −1 to −5 V, preferably −3 V. It has been shown in FIG. 3 that the conductive interference shielding lines Line1 and Line2 are formed both between the drain select line DSL and the word line WLn and between the source select line SSL and the word line WL0. It is, however, to be noted that the conductive interference shielding lines Line1 and Line2 may be formed either between the drain select line DSL and the word line WLn or between the source select line SSL and the word line WL0.

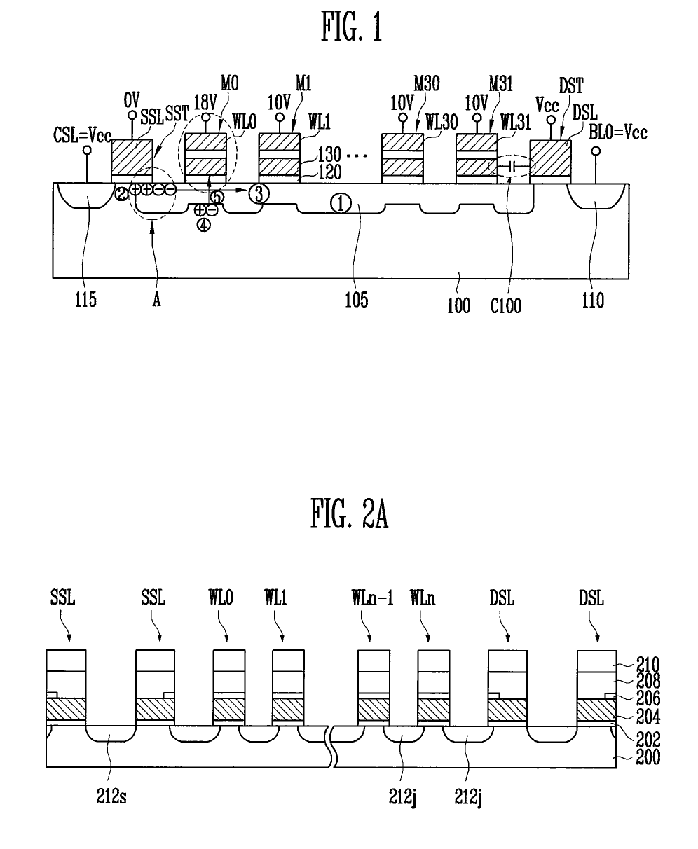

If a program operation is performed under the above condition, an electric field formed by the negative potential bias applied to the conductive line Line1 is transferred to the semiconductor substrate. Thus, the electric field transferred to the semiconductor substrate hinders hot carriers (refer to FIG. 1), which are generated from the junction region of the select transistor, from moving in a memory cell direction. That is, since hot carriers can be prevented from moving to a memory cell connected to the word lines adjacent to the select line, hot carriers can be prevented from being injected into the floating gate. It is therefore possible to prevent the threshold voltage of a memory cell adjacent to the select line from varying.

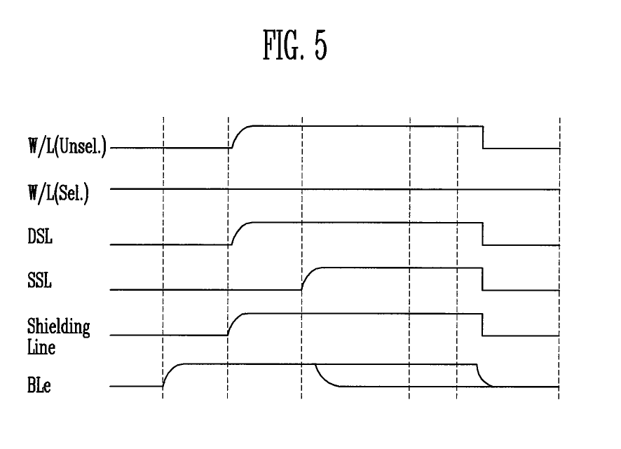

FIG. 4 is a circuit diagram illustrating a method of programming a non-volatile memory device according to a second embodiment of the present invention. FIG. 5 is a timing diagram illustrating bias applied in the program method of FIG. 4.

Referring to FIGS. 4 and 5, in a similar way as the conductions described with reference to FIG. 3, the bit lines BL0 and BL1, the drain select line DSL, the source select line SSL, the word lines WL0 to WLn and the common source line CSL are applied with a bias for a program operation. The conductive interference shielding line Line1 is applied with a bias, which is higher than the voltage applied to the drain select line DSL, but lower than 5 V. The conductive interference shielding line Line1 may be preferably applied with 3 V.

The conductive interference shielding line Line1 between the drain select line DSL and the word line WLn is applied with a positive potential bias in order to minimize capacitance coupling between the drain select line DSL and the word line WLn. Thus, the voltage boosting level of the channel region can be prevented from lowering in order to hinder the program operation.

If the voltage boosting level of the channel region is lowered as described above, a voltage difference between the word lines and the channel region is increased and memory cells can be programmed abnormally. Accordingly, the threshold voltage of the memory cells may be changed. However, if the positive potential bias is applied to the conductive interference shielding line Line1 between the drain select line DSL and the word line WLn, the voltage boosting level of the channel region can be prevented from lowering and the threshold voltage of the memory cells can be prevented from changing.

Meanwhile, the boosting level of the channel region can be lowered by the positive potential bias applied to the conductive interference shielding line Line1. For example, if the positive potential bias is applied later than the pass voltage Vpass applied to unselected word lines, the boosting level of the channel region can be lowered since the channel region can be prevented from being precharged. Accordingly, it is important to control timing at which the positive potential bias is applied to the conductive interference shielding line Line1. In more detail, for example, the positive potential bias may be applied to the conductive interference shielding line Line1 at least at the same time as or earlier than the pass voltage Vpass applied to unselected word lines.

In the above, the program method of preventing hot carriers from being injected into the floating gate of the memory cell and the program method of preventing the boosting level of the channel region from lowering have been described. However, in the case where the two problems are to be prevented at the same time, a positive potential bias can be applied to the conductive interference shielding line Line1 between the drain select line DSL and the word line WLn and a negative potential bias can be applied to the conductive interference shielding line Line2 between the source select line SSL and the word line WL0.

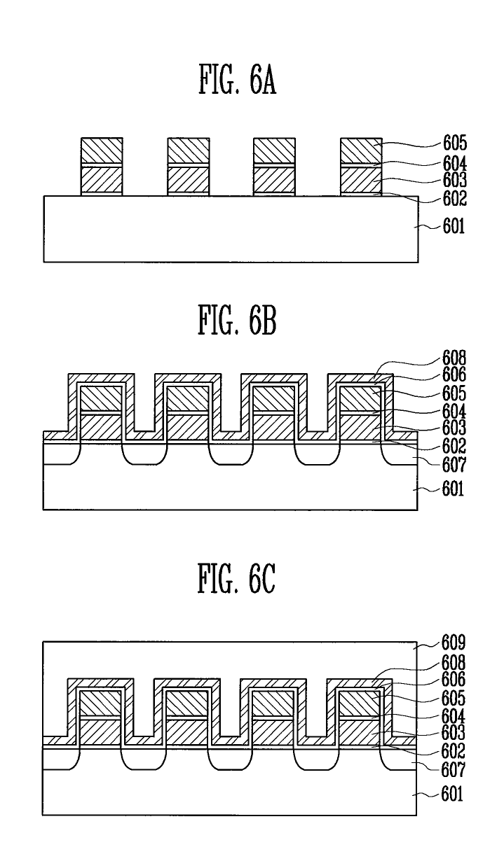

FIGS. 6A to 6C are cross-sectional views sequentially illustrating a method of manufacturing a flash memory device according to another embodiment of the present invention.

Referring to FIG. 6A, an isolation layer (not shown) is formed over a predetermined region of a semiconductor substrate 601, defining an active region and a field region. A tunnel oxidization layer 602 (or tunnel dielectric layer) and a first conductive layer 603 are formed over the semiconductor substrate 601 of the active region to form a floating gate pattern.

The floating gate pattern and the isolation layer (not shown) may be formed by a Self-Aligned Shallow Trench Isolation (SA-STI) or Self-Aligned Floating Gate (SAFG) process in the present embodiment. The floating gate pattern is formed in a parallel direction to the isolation layer (not shown). In the case where the floating gate is formed by the SA-STI process, the first conductive layer 603 may be formed by laminating a plurality of polysilicon layers, e.g., first and second polysilicon layers. In the case where the floating gate is formed by the SAFG process, the first conductive layer 603 may be formed by a single polysilicon layer.

A first dielectric layer 604 and a second conductive layer 605 are formed over the floating gate and the substrate. Predetermined regions of the second conductive layer 605 and the first dielectric layer 604 are patterned by a photolithography process using a control gate mask. The control gate is formed in a vertical direction to the isolation layer (not shown). The underlying first conductive layer 603 is then etched to form a floating gate. Accordingly, a cell gate in which the floating gate and the control gate are laminated is formed.

Referring to FIG. 6B, to compensate for etch damage over the sides of the cell gate, which occurs during the etch process for forming the cell gate, an oxidization process is performed. An insulating layer 606 is thereby formed over the cell gate and the semiconductor substrate 601. The insulating layer 606 has a thickness of 10 Å to 500 Å. The insulating layer 606 is an oxide layer. In another embodiment, a dielectric layer other than oxide is used for the layer 606.

An ion implant process is performed to form a junction region 607 over the semiconductor substrate 601 between the cell gates. An interference shielding line 608 is formed over the insulating layer 606 and the junction regions 607. In the present embodiment, the interference shielding line 608 is formed only in the cell region, so that subsequent processes, e.g., source/drain formation, well pick-up formation, etc., would not be hindered.

The interference shielding line 608 may be formed to a thickness of 10 to 1000 Å using a conductive layer. In the present embodiment, the interference shielding line 608 includes oxide or nitride. For example, the interference shielding line 608 is a conductive oxide or a conductive nitride according to one implementation. In alternative or in combination, the interference shielding line 608 includes a polysilicon layer, a titanium layer, a tungsten layer or a cobalt layer, or combination thereof. During an operation of the flash memory, the interference shielding line 608 is applied with a bias or a voltage (e.g., −30 to 30 V), so that the interference shielding line 608 does not become a floating state. In one implementation, the bias is between −15 to 15 volts. In another implementation, the bias is between −10 and 10 volts. Referring to FIG. 6C, the space between the cell gates are gap-filled with a nitride layer 609. The nitride layer 609 is for the purpose of forming a spacer for a self-aligned contact process over the sides of the gate of a select transistor region. If the spacer is formed over the sides of the gate of the select transistor, the distance between the cell gates can be made small. Accordingly, the space between the cell gates can be fully gap-filled.

As described above, according to the present invention, electrodes isolated from the semiconductor substrate are formed between the select line and the word lines. At the time of a program operation, a bias is applied in order to prevent hot carriers from moving to memory cells and also minimizing capacitance coupling between the word lines and the select line. Accordingly, the threshold voltage of a memory cell that must maintain an erase state at the time of a program operation can be prevented from changing.

Although the foregoing description has been made with reference to the various embodiments, it is to be understood that changes and modifications of the present patent may be made by the ordinary skilled in the art without departing from the spirit and scope of the present patent and appended claims.

What is claimed is:

1. A non-volatile memory device comprising:
a plurality of select lines and a plurality of word lines formed over a semiconductor substrate;
a contact plug formed between the select lines; and
an interference shielding line of conductive material formed between the select line and a word line adjacent to the select line and isolated from the semiconductor substrate.

2. The non-volatile memory device of the claim 1, wherein the interference shielding line is formed between a source select line of the select lines and a word line adjacent to the source select line and is isolated from the semiconductor substrate.

3. The non-volatile memory device of claim 1, wherein the interference shielding line is formed between a drain select line of the select lines and a word line adjacent to the drain select line and is isolated from the semiconductor substrate.

4. The non-volatile memory device of claim 1, the interference shielding line is formed between the drain select line and a word line adjacent to the drain select line and between the source select line and a word line adjacent to the source select line and is isolated from the semiconductor substrate.

5. The non-volatile memory device of claim 1, wherein the conductive material comprises at least one of polysilicon, titanium, cobalt or tungsten, or combination thereof.

6. The non-volatile memory device of claim 1, further comprising a junction region formed in the semiconductor substrate between the select lines and the word lines.

7. The non-volatile memory device of claim 1, further comprising an insulating layer for electrically isolating the interference shielding line from the select lines and the word lines.

8. A method of manufacturing a non-volatile memory device, comprising:
providing a semiconductor substrate in which a plurality of select lines and a plurality of word lines are formed;
forming a first insulating layer over the semiconductor substrate including the select lines and the word lines;
removing the first insulating layer between the select linesforming a interference shielding line of conductive material over the first insulating layer between the select line and a word line adjacent to the select line;
forming a second insulating layer over the semiconductor substrate including the interference shielding line.

9. The method of manufacturing the non-volatile memory device of claim 8, further comprising the step of etching the second insulating layer to expose the semiconductor substrate and the interference shielding line between the select lines, thus forming a contact hole; and
forming a contact plug within the contact hole.

10. The method of manufacturing the non-volatile memory device of claim 8, further comprising the step of forming a junction region in the semiconductor substrate between the select lines and the word lines before the first insulating layer is formed.

11. The method of manufacturing the non-volatile memory device of claim 8, wherein the interference shielding line is formed between a source select line of the select lines and a word line adjacent to the source select line and is isolated from the semiconductor substrate.

12. The method of manufacturing the non-volatile memory device of claim 8, wherein the interference shielding line is formed between a drain select line of the select lines and a word line adjacent to the drain select line and is isolated from the semiconductor substrate.

13. The method of manufacturing the non-volatile memory device of claim 8, wherein the
the interference shielding line is formed between the drain select line and a word line adjacent to the drain select line and between the source select line and a word line adjacent to the source select line, and is isolated from the semiconductor substrate and is isolated from the semiconductor substrate.

14. The method of manufacturing the non-volatile memory device of claim 8, wherein the conductive material comprises at least one of polysilicon, titanium, cobalt or tungsten, or combination thereof.

15. A method of programming a non-volatile memory device, comprising the steps of:
providing a non-volatile memory device in which a plurality of word lines and a plurality of select lines are formed over a semiconductor substrate, and an interference shielding line of conductive material is formed between the word line and the select line; and
performing a program operation while applying a negative potential bias to the interference shielding line.

16. The method of claim 15, wherein
the interference shielding line is provided between the source select line of the select lines and a word line adjacent to the source select line and is isolated from the semiconductor substrate.

17. The method of claim 15, wherein
the interference shielding line is provided between the drain select line of the select lines and a word line adjacent to the drain select line and is isolated from the semiconductor substrate.

18. The method of claim 15, wherein
the interference shielding line is provided between the source select line of the select lines and a word line adjacent to the source select line and between the drain select line of the select lines and a word line adjacent to the drain select line and is isolated from the semiconductor substrate.

19. The method of claim 15, wherein the interference shielding line is applied with a negative potential bias of −1 to −5 V.

20. A method of programming a non-volatile memory device, comprising the steps of:
providing a non-volatile memory device in which a plurality of word lines and a plurality of select lines are formed over a semiconductor substrate, and a first interference shielding line of conductive material is provided between a drain select line of the select lines and a word line adjacent to the drain select line and is isolated from the semiconductor substrate; and
performing a program operation while applying a positive potential bias to the first interference shielding line.

21. The method of claim 20, wherein the positive potential bias is applied at the same timing as or earlier than a bias applied to word lines that are not selected at the time of a program operation, of the word lines.

22. The method of claim 20, wherein the positive potential bias applied to the first interference shielding line is higher than a bias applied to the drain select line at the time of a program operation, but lower than 5 V.

23. The method of claim 20, further comprising,
a second interference shielding line of the conductive material is provided between a source select line of the select lines and a word line adjacent to the source select line and is isolated from the semiconductor substrate, and
a negative potential bias is applied to the second interference shielding line during the program operation.

24. The method of claim 23, wherein the second interference shielding line is applied with a negative potential bias of −1 to −5 V.

25. A non-volatile memory device, comprising:
a cell gate including a floating gate and a control gate;
an insulating layer formed over the cell gate; and
a interference shielding line of the conductive material formed over the insulating layer.

26. The non-volatile memory device of claim 25, further comprising a junction region formed adjacent to the cell gate and in a semiconductor substrate.

27. The non-volatile memory device of claim 25, wherein the conductive material comprises at least one of polysilicon, titanium, tungsten, or cobalt, or combination thereof.

28. The non-volatile memory device of claim 25, wherein the interference shielding line is biased with a given potential during an operation of the non-volatile memory device.

29. The non-volatile memory device of claim 25, wherein the insulating layer is an oxide layer.

30. The non-volatile memory device of claim 28, wherein the bias is set within a range of −30 to 30 V.

31. A method of manufacturing a non-volatile memory device, the method comprising:
forming a cell gate including a floating gate and a control gate over a semiconductor substrate;
forming an insulating layer over the cell gate and the semiconductor substrate; and
forming an interference shielding line of conductive material over the insulating layer.

32. The method of claim 31, further comprising forming a junction region over the semiconductor substrate adjacent to the cell gate; and

33. The method of claim 31, wherein the conductive material comprises at least one of polysilicon, titanium, tungsten, or cobalt, or combination thereof.

34. The method of claim 31, wherein the interference shielding line is formed to a thickness of 10 to 1000 Å.

35. The method of claim 31, wherein the interference shielding line is provided with a bias while performing an operation to the memory device.

36. The method of claim 35, wherein the interference shielding line conforms to the shape of the cell gate, wherein the interference shielding line is provided over an active region and not over a field region.

37. The method of claim 35, wherein the bias is set within a range of −30 to 30 V.

38. A method of manufacturing a non-volatile memory device, the method comprising:
forming first and second cell gates over a semiconductor substrate;
forming an insulating layer over the first and second cell gates; and
forming an interference shielding line of the conductive material over the insulating layer and between the first and second cell gates.

39. The method of claim 38, wherein the conductive material comprises at least one of polysilicon, titanium, tungsten, or cobalt, or combination thereof.

40. The method of claim 38, wherein the interference shielding line is formed to a thickness of 10 to 1000 Å.

41. The method of claim 38, wherein the interference shielding line is configured to be applied with a bias during an operation of the memory device.

42. The method of claim 38, wherein the interference shielding line is provided over an active region but not over a field region.

43. The method of claim 42, wherein the interference shielding line is configured to be applied with a bias during an operation of the memory device, the bias being within a range of −30 to 30 V.
